(19) United States
(12) Patent Application Publication
(10) Pub. No.: US 2018/0082880 A1
(43) Pub. Date: Mar. 22, 2018

(54) SUBSTRATE HOLDING APPARATUS

(71) Applicant: TOSHIBA MEMORY CORPORATION, Tokyo (JP)

(72) Inventor: Nobuhiro KOMINE, Nagoya (JP)

(73) Assignee: TOSHIBA MEMORY CORPORATION, Tokyo (JP)

(21) Appl. No.: 15/449,278

(22) Filed: Mar. 3, 2017

(30) Foreign Application Priority Data
Sep. 16, 2016 (JP) 2016-181865

(51) Int. Cl. H01L 21/683; G03F 7/20

(52) U.S. Cl. CPC H01L 21/6838; G03F 7/707

(57) ABSTRACT

A substrate holding apparatus includes a placing portion, a first depressurization unit, a second depressurization unit, a storage unit and a control unit. The placing portion includes a plurality of convex portions supporting a substrate, and includes a first region which faces a center portion of the substrate and second regions which face outer peripheral portions of the substrate. The first depressurization unit is configured to depressurize a space between the substrate and the first region. The second depressurization unit is configured to depressurize a space between the substrate and the second regions. The storage unit is configured to store shape information of the substrate. The control unit is configured to individually control each of the first depressurization unit and the second depressurization unit based on the shape information.

### CROSS-REFERENCE TO RELATED APPLICATION

This application claims the benefit of and priority to Japanese Patent Application No. 2016-181865, filed Sep. 16, 2016, the entire contents of which are incorporated herein by reference.

### FIELD

Embodiments described herein relate generally to a substrate holding apparatus.

### BACKGROUND

In a semiconductor manufacturing process such as a photolithography process or the like, when particles are caught between a stage and a substrate, a problem such as local defocus occurs. In order to prevent such a problem, a pin contact type vacuum chuck is used. The pin contact type vacuum chuck can apply suction to the substrate in a planar shape even when there are particles on the stage, by supporting the substrate by a plurality of protrusions provided on the surface of the stage and reducing the contact area between the stage and the substrate. However, improvements in such pin contact type vacuum chucks remain desired.

### SUMMARY

In some embodiments according to one aspect, a substrate holding apparatus including a placing portion, a first depressurization unit, a second depressurization unit, a storage unit and a control unit. The placing portion may include a plurality of projection portions supporting a substrate, and include a first region which faces a center portion of the substrate and second regions which face outer peripheral portions of the substrate. The first depressurization unit may be configured to depressurize a space between the substrate and the first region. The second depressurization unit may be configured to depressurize a space between the substrate and the second regions. The storage unit may be configured to store shape information of the substrate. The control unit may be configured to individually control each of the first depressurization unit and the second depressurization unit based on the shape information.

Other aspects and embodiments of the disclosure are also encompassed. The foregoing summary and the following detailed description are not meant to restrict the disclosure to any particular embodiment but are merely meant to describe some embodiments of the disclosure.

### DESCRIPTION OF THE DRAWINGS

FIG. 1 is a diagram illustrating a configuration example of a substrate holding apparatus according to some embodiments.

FIG. 2 is a plan view illustrating a configuration example of a stage.

FIG. 3A is a graph illustrating the distortion measurement result of a substrate with a convex (or projection-shaped) distortion, and FIG. 3B is a graph illustrating the distortion measurement result of a substrate with a concave (or recess-shaped) distortion.

FIG. 4 is a flowchart illustrating an example of a substrate holding method according to some embodiments.

FIG. 5A, FIG. 5B, FIG. 5C, and FIG. 5D are sectional views illustrating an example of the substrate holding method according to some embodiments.

FIG. 6A, FIG. 6B and FIG. 6C are sectional views illustrating an example of the substrate holding method according to some embodiments.

FIG. 7 is a graph illustrating the distortion measurement result of a substrate with a saddle-shaped distortion.

FIG. 8A and FIG. 8B are diagrams illustrating a configuration example of a substrate holding apparatus according to some embodiments.

FIG. 9 is a plan view illustrating a configuration example of a stage according to some embodiments.

FIG. 10 is a flowchart illustrating an example of a substrate holding method according to some embodiments.

### DETAILED DESCRIPTION

In a semiconductor manufacturing process such as a photolithography process or the like, a pin contact type vacuum chuck can be used to apply suction to the substrate in a planar shape even when there are particles on the stage, by supporting the substrate by a plurality of protrusions provided on the surface of the stage and reducing the contact area between the stage and the substrate. However, when applying suction to a substrate with a distortion on the stage by correcting the distortion of the substrate in a planar shape, in some cases, the pin contact type vacuum chuck cannot correct the distortion of the substrate in a planar shape depending on the shape of the distortion, and as a result, there is a problem that the substrate cannot be drawn to the stage.

An example embodiment provides a substrate holding apparatus capable of applying suction to a substrate in a planar shape by correcting the distortion of the substrate regardless of the shape of the distortion.

According to some embodiments, a substrate holding apparatus may include a placing portion, a first depressurization unit, a second depressurization unit, a storage unit and a control unit. The placing portion may include a plurality of convex portions (or projection portions) which can support a substrate, and include a first region which faces the center portion of the substrate and second regions which face the outer peripheral portions of the substrate. The first depressurization unit may depressurize the space between the substrate and the first region. The second depressurization unit may depressurize the space between the substrate and the second regions. The storage unit may store shape information of the substrate. The control unit can individually control each of the first depressurization unit and the second depressurization unit based on the shape information.

Hereinafter, embodiments of the present disclosure will be described with reference to the drawings. The embodiments described herein do not limit the present disclosure.

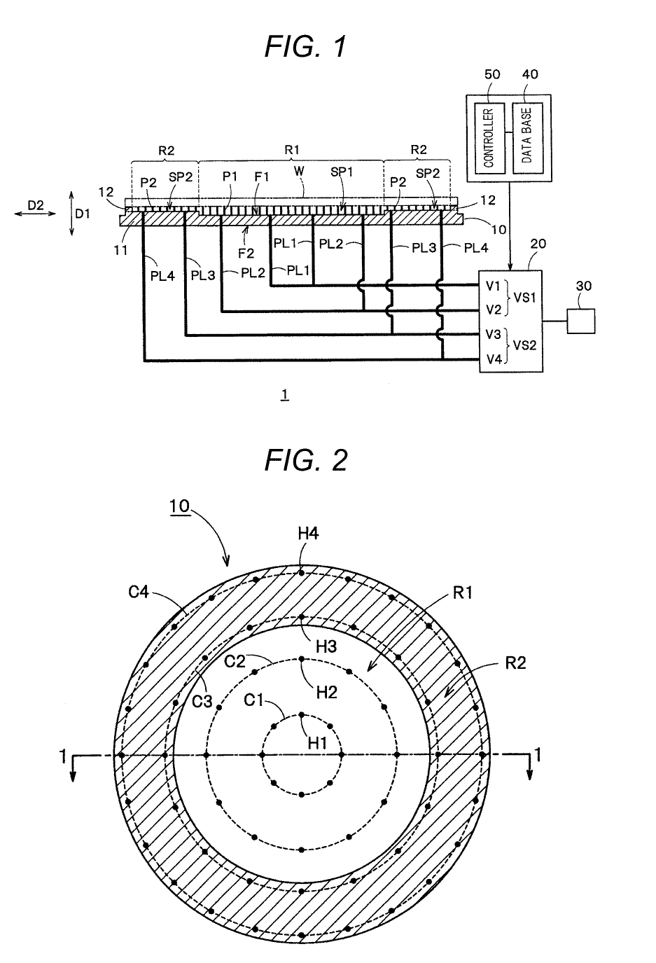

FIG. 1 is a diagram illustrating a configuration example of a substrate holding apparatus 1 according to some embodiments. The substrate holding apparatus 1 is provided, for example, in an exposure apparatus or the like in a photolithography process, and holds a substrate W at the time of exposure. The substrate holding apparatus 1 is, for example, a pin contact type chuck, and applies suction to and holds the substrate on a stage 10 by evacuating the space between the substrate W and the stage 10. In some embodiments, the substrate holding apparatus 1 can also be applied to a semiconductor manufacturing apparatus other than the exposure apparatus or other apparatuses other than the semiconductor manufacturing apparatus.

In some embodiments, the substrate holding apparatus 1 includes the stage 10, a valve mechanism 20, a vacuum pump 30, a database 40, a controller 50, and exhaust pipes PL1 to PL4.

In some embodiments, the stage 10 as a placing portion includes a support portion 11, convex portions P1 and P2, and partition portions 12. In some embodiments, the stage 10 includes a first region R1 and second regions R2. In some embodiments, the first region R1 is positioned at the center portion of the stage 10, and is a region that faces the center portion of the substrate W placed on the convex portions P1 and P2. In some embodiments, the second region R2 is positioned at the outer peripheral portion of the stage 10, and is a region that faces the outer peripheral portion of the substrate W placed on the convex portions P1 and P2. In some embodiments, as illustrated in FIG. 2, the stage 10 has substantially the same shape (for example, a circular shape) as that of the substrate W, and is slightly larger than the substrate W. The stage 10 is made of, for example, a material such as ceramic. The cross-section taken along line 1-1 of FIG. 2 is illustrated as the stage 10 in FIG. 1. The plan layout of the stage 10 will be described later with reference to FIG. 2.

In some embodiments, the support portion 11 is positioned at the bottom of the stage 10 as a main body. In some embodiments, the thickness of the support portion 11 in the first region R1 is thinner than the thickness of the support portion 11 in the second region R2. In some embodiments, the bottom surface (second surface F2) of the stage 10 is substantially flat. In some embodiments, the second surface F2 is the surface opposite to the first surface F1 of the support portion 11. In some embodiments, the support portion 11 in the first region R1 is deeper (or lower) than the support portion 11 in the second region R2 in the direction perpendicular to the first surface F1. In some embodiments, in a direction D1 which faces the substrate W, the first surface F1 in the second region R2 is higher than the first surface F1 in the first region R1, and the first surface F1 in the second region R2 is close to the tips of the second convex portions P2. In some embodiments, the first surface F1 is a surface on which the substrate W is placed, and is a surface that faces the substrate W when the substrate W is placed on the first surface F1. In some embodiments, the first surface F1 in the first region R1 faces the center portion of the substrate W, and the first surface F1 in the second region R2 faces the outer peripheral portion of the substrate W.

In some embodiments, the plurality of convex portions P1 and P2 are provided on the first surface F1 of the support portion 11. In some embodiments, the first convex portions P1 are provided in the first region R1 on the first surface F1, and the second convex portions P2 are provided in the second region R2 on the first surface F1. In some embodiments, the first convex portions P1 are longer than the second convex portions P2 in the D1 direction. In some embodiments, the difference in length between the first convex portions P1 and the second convex portions P2 is substantially equal to the difference in depth (or height) between the first surface F1 in the first region R1 and the first surface F1 in the second region R2. Accordingly, in some embodiments, the tips of the first and second convex portions P1 and P2 are in substantially the same plane (for example, a horizontal plane) in a D2 direction orthogonal to the D1 direction, and thus the first and second convex portions P1 and P2 can support the substrate W of which the bottom surface is brought into contact with the tips thereof on substantially the same plane (for example, a horizontal plane). In some embodiments, the plane that connects the tips of the first convex portions P1 and the tips of the second convex portions P2 becomes the placement plane of the substrate W. The diameters of the convex portions P1 and P2 in the direction D2 may be, for example, in a range from approximately 0.1 mm to approximately 1 mm. The heights of the convex portions P1 and P2 in the direction D1 are different from each other, but may be, for example, in a range from approximately several tens of μm to approximately several hundreds of μm. In some embodiments, the sectional shapes of the convex portions P1 and P2 in the direction D2 may be a circular shape, a quadrangular shape, a triangular shape, or the like, for example. The sectional shapes of the convex portions P1 and P2 in the direction D1 may be an inverted T shape, a rectangular shape, a triangular shape, or the like, for example. The convex portions P1 and P2 may be two-dimensionally arranged on the first surface F1 at intervals of approximately 1 mm to approximately 3 mm, for example.

In some embodiments, the partition portions 12 are provided at the outer edge of the support portion 11, and project from the first surface F1 of the support portion 11. In some embodiments, the lengths of the partition portions 12 may be substantially the same as the lengths of the second convex portions P2. In some embodiments, the tips of the partition portions 12 are on substantially the same plane (for example, a horizontal plane) as the plane on which the tips of the first and second convex portions P1 and P2 are present, and brought into contact with the outer edge portion of the bottom surface of the substrate W. In some embodiments, the partition portions 12 can support the substrate W on substantially the same plane (for example, a horizontal plane) together with the first and second convex portions P1 and P2. In some embodiments, the tips of the partition portions 12 are in the placement plane of the substrate W together with the tips of the first and second convex portions P1 and P2. In some embodiments, the partition portions 12 allows the space between the substrate W and the support portion 11 to be evacuated by separating the space between the substrate W and the support portion 11 from the outside. The support portion 11, the convex portions P1 and P2, and the partition portion 12 are integrally formed as the stage 10, and made of, for example, a ceramic material as described above.

In some embodiments, the exhaust pipes PL1 to PL4 are drawn from the first surface F1 of the support portion 11 to the second surface F2 opposite to the first surface F1, and connected to the valve mechanism 20. In some embodiments, the exhaust pipes PL1 to PL4 connect the first and second spaces SP1 and SP2 between the substrate W and the support portion 11 to the valve mechanism 20. Accordingly, in some embodiments, the vacuum pump 30 can evacuate and depressurize the first and second spaces SP1 and SP2 via the valve mechanism 20 and the exhaust pipes PL1 to PL4. In some embodiments, the first space SP1 is a space between the substrate W and the stage 10 in the first region R1. In some embodiments, the second space SP2 is a space between the substrate W and the stage 10 in the second region R2.

In some embodiments, the exhaust pipes PL1 are connected between the first space SP1 and a valve V1, and the exhaust pipes PL2 are connected between the first space SP1 and a valve V2. In some embodiments, the exhaust pipes PL3 are connected between the second space SP2 and a valve V3, and the exhaust pipes PL4 are connected between the second space SP2 and a valve V4.

In some embodiments, the exhaust pipes PL1 communicate with the position closest to the center portion of the stage 10 among the exhaust pipes PL1 to PL4 on the first surface F1. In some embodiments, the exhaust pipes PL2 are provided around the exhaust pipes PL1 on the first surface F1, and communicate with the position second closest to the center portion of the stage 10 among the exhaust pipes PL1 to PL4 on the first surface F1. In some embodiments, the exhaust pipes PL3 and PL4 are provided around the exhaust pipes PL1 and PL2 on the first surface F1. In some embodiments, the exhaust pipes PL3 communicate with the position third closest to the center portion of the stage 10 among the exhaust pipes PL1 to PL4 on the first surface F1. In some embodiments, the exhaust pipes PL4 communicate with the position farthest from the center portion of the stage 10 and closest to the outer edge of the stage 10 among the exhaust pipes PL1 to PL4 on the first surface F1.

In some embodiments, the valve mechanism 20 includes the valves V1 to V4. In some embodiments, the valve V1 is provided between the exhaust pipes PL1 and the vacuum pump 30, and can allow or block (open or close) the connection between the exhaust pipes PL1 and the vacuum pump 30. In some embodiments, when the valve V1 is opened, the first space SP1 is evacuated via the exhaust pipes PL1. In some embodiments, when the valve V1 is closed, the first space SP1 is not evacuated from the exhaust pipes PL1. In some embodiments, the valve V2 is provided between the exhaust pipes PL2 and the vacuum pump 30, and can allow or block (open or close) the connection between the exhaust pipes PL2 and the vacuum pump 30. In some embodiments, when the valve V2 is opened, the first space SP1 is evacuated via the exhaust pipes PL2. In some embodiments, when the valve V2 is closed, the first space SP1 is not evacuated from the exhaust pipes PL2. In some embodiments, the valve V3 is provided between the exhaust pipes PL3 and the vacuum pump 30, and can allow or block (open or close) the connection between the exhaust pipes PL3 and the vacuum pump 30. In some embodiments, when the valve V3 is opened, the second space SP2 is evacuated via the exhaust pipes PL3. In some embodiments, when the valve V3 is closed, the second space SP2 is not evacuated from the exhaust pipes PL3. In some embodiments, the valve V4 is provided between the exhaust pipes PL4 and the vacuum pump 30, and can allow or block (open or close) the connection between the exhaust pipes PL4 and the vacuum pump 30. In some embodiments, when the valve V4 is opened, the second space SP2 is evacuated via the exhaust pipes PL4. In some embodiments, when the valve V4 is closed, the second space SP2 is not evacuated from the exhaust pipes PL4.

In some embodiments, the valve mechanism 20 can evacuate the spaces (SP1 and SP2) between the substrate W and the stage 10 at locally different timings by controlling the valves V1 to V4. In some embodiments, the spaces SP1 and SP2 communicate with each other, so that in a case where the outer edge portions of the substrate W come into contact with the partition portions 12 and the spaces SP1 and SP2 are substantially sealed, when any one of the spaces SP1 and SP2 is evacuated, the spaces SP1 and SP2 are entirely depressurized. On the other hand, in a case where the substrate W is distorted and the spaces SP1 and SP2 are not sealed, the valve mechanism 20 can not sufficiently depressurize the entire of the spaces SP1 and SP2, but can attract a portion of the substrate W to the stage 10 by controlling the valves V1 to V4.

In some embodiments, the vacuum pump 30 evacuates the spaces SP1 and SP2 via the valve mechanism 20 and the exhaust pipes PL1 to PL4. In some embodiments, the vacuum pump 30 is commonly provided for the valve mechanism 20 and the exhaust pipes PL1 to PL4, and can selectively evacuate the exhaust pipes PL1 to PL4 by controlling the valves V1 to V4. In some embodiments, the valves V1 to V4 may be omitted, and the vacuum pump 30 may be provided for each of the exhaust pipes PL1 to PL4. In this case, the controller 50 may individually control the vacuum pump corresponding to each of the exhaust pipes PL1 to PL4. Even in this case, it is possible to selectively evacuate the exhaust pipes PL1 to PL4.

FIG. 2 is a plan view illustrating a configuration example of the stage 10. In some embodiments, exhaust holes H1 that communicate with the exhaust pipes PL1 are arranged on a broken-line circle C1. In some embodiments, exhaust holes H2 that communicate with the exhaust pipes PL2 are arranged on a broken-line circle C2. In some embodiments, exhaust holes H3 that communicate with the exhaust pipes PL3 are arranged on a broken-line circle C3. In some embodiments, exhaust holes H4 that communicate with the exhaust pipes PL4 are arranged on a broken-line circle C4. The broken-line circles C1 to C4 are virtual concentric circles having the center of the stage 10 as a center. In this way, in some embodiments, the exhaust pipes PL1 to PL4 are respectively connected to the exhaust holes H1 to H4 that are concentrically arranged from the center of the stage 10. The number of each of the exhaust holes H1 to H4 is not particularly limited. In some embodiments, the exhaust holes H1 to H4 are substantially evenly arranged on the broken-line circles C1 to C4.

In some embodiments, a first depressurization unit VS1 is an exhaust system that depressurizes the first space SP1, and includes any one or both of an exhaust system (a first system) that is configured with the exhaust pipes PL1, the valve V1, and the vacuum pump 30, and an exhaust system (a second system) that is configured with the exhaust pipes PL2, the valve V2, and the vacuum pump 30. In some embodiments, when any one or both of the first system and the second system perform evacuation, the first depressurization unit VS1 performs depressurization. In some embodiments, when both of the first system and the second system stop evacuation, the first depressurization unit VS1 stops depressurization. In some embodiments, a second depressurization unit VS2 is an exhaust system that depressurizes the second spaces SP2, and includes any one or both of an exhaust system (a third system) that is configured with the exhaust pipes PL3, the valve V3, and the vacuum pump 30, and an exhaust system (a fourth system) that is configured with the exhaust pipes PL4, the valve V4, and the vacuum pump 30. In some embodiments, when any one or both of the third system and the fourth system perform evacuation, the second depressurization unit VS2 performs depressurization. In some embodiments, when both of the third system and the fourth system stop evacuation, the second depressurization unit VS2 stops depressurization.

In some embodiments, the number of the depressurization units and the number of the exhaust systems (the exhaust pipes and the valves) may be two or more, but are not particularly limited. In some embodiments, similar to the depressurization unit, the number of the regions on the first face F1 of the support portion 11 may be two or more, but is not particularly limited.

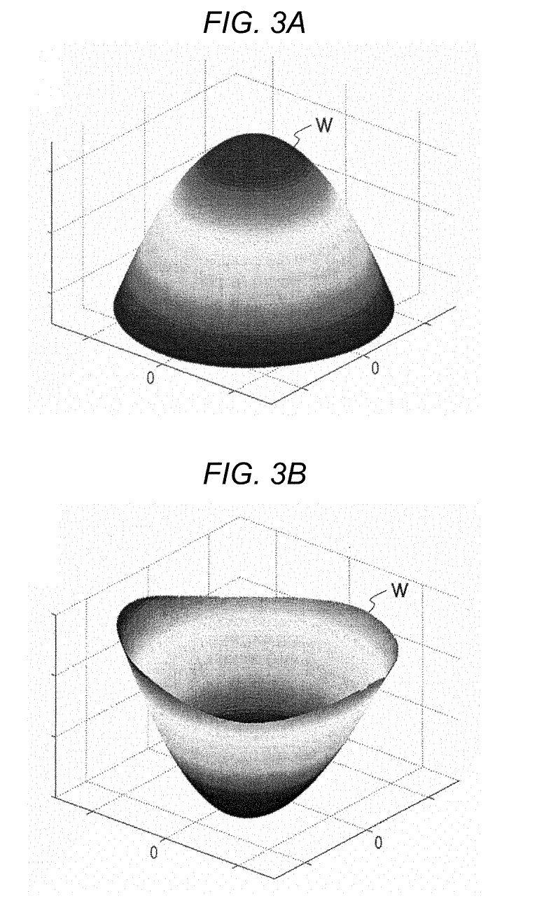

In some embodiments, the database 40 as a storage unit stores the shape information of the substrate W. The shape information of the substrate W can be obtained, for example, based on a distortion measurement value of the substrate W that is measured by using a distortion measurement apparatus. For example, when a plurality of memory layers are stacked on the substrate W as in a three-dimensional memory, the substrate W tends to be distorted by the stress of the plurality of memory layers. In some embodiments, the distortion of the substrate W can be classified into a convex (or projection-shaped or umbrella-shaped) distortion and a concave (or recess-shaped or bowl-shaped) distortion as illustrated in FIGS. 3A and 3B. FIG. 3A is a graph illustrating the distortion measurement result of the substrate W with the convex (or projection-shaped or umbrella-shaped) distortion. FIG. 3B is a graph illustrating the distortion measurement result of the substrate W with the concave (or recess-shaped or bowl-shaped) distortion. Since FIGS. 3A and 3B exaggeratedly illustrate the distortions in order to easily find the distortions, the distortions may be different from actual distortions of the substrate W in some cases.

In some embodiments, in the convex distortion, the center portion of the substrate W is further projected in a direction farther away from the stage 10 than the end portions of the substrate W. In some embodiments, in the concave (or recess-shaped) distortion, the center portion of the substrate W is further projected (or recessed) in a direction closer to the stage 10 than the end portions of the substrate W. The shape information of the substrate W may be, for example, bit data indicating the convex (or projection-shaped) distortion or the concave (or recess-shaped) distortion based on the distortion measurement value. The distortion measurement apparatus may be separately provided from the substrate holding apparatus 1, or may be incorporated in the substrate holding apparatus 1.

In some embodiments, the controller 50 as a control unit controls the valve mechanism 20 using a control sequence which is set in advance based on the shape information of the substrate W that is stored in the database 40. In some embodiments, the controller 50 changes the order of the depressurization operation of the valves V1 to V4 according to the shape information. In some embodiments, the controller 50 changes an opening/closing sequence of the valves V1 to V4 depending on whether the substrate W has the convex (or projection-shaped) distortion or the concave (or recess-shaped) distortion. In some embodiments, the opening/closing sequence of the valves V1 to V4 may be configured as a program, and stored in the database 40 in advance. In some embodiments, the controller 50 may be a general-purpose central processing unit (CPU). In some embodiments, the opening/closing sequence of the valves V1 to V4 may be configured as a logic circuit in the controller 50. In some embodiments, the controller 50 can individually (or independently) control the first depressurization unit and the second depressurization unit by using the program or the logic circuit.

Next, a substrate holding method using the substrate holding apparatus 1 will be described.

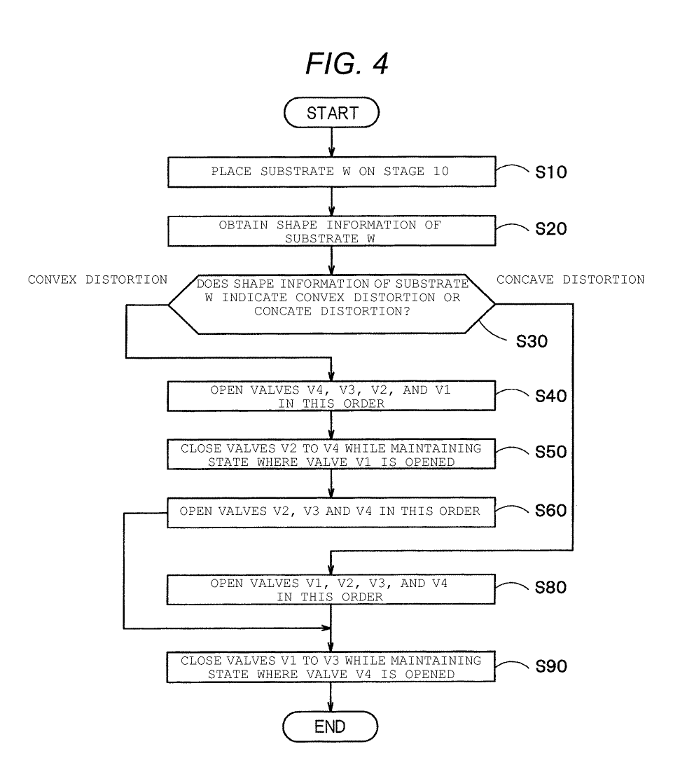

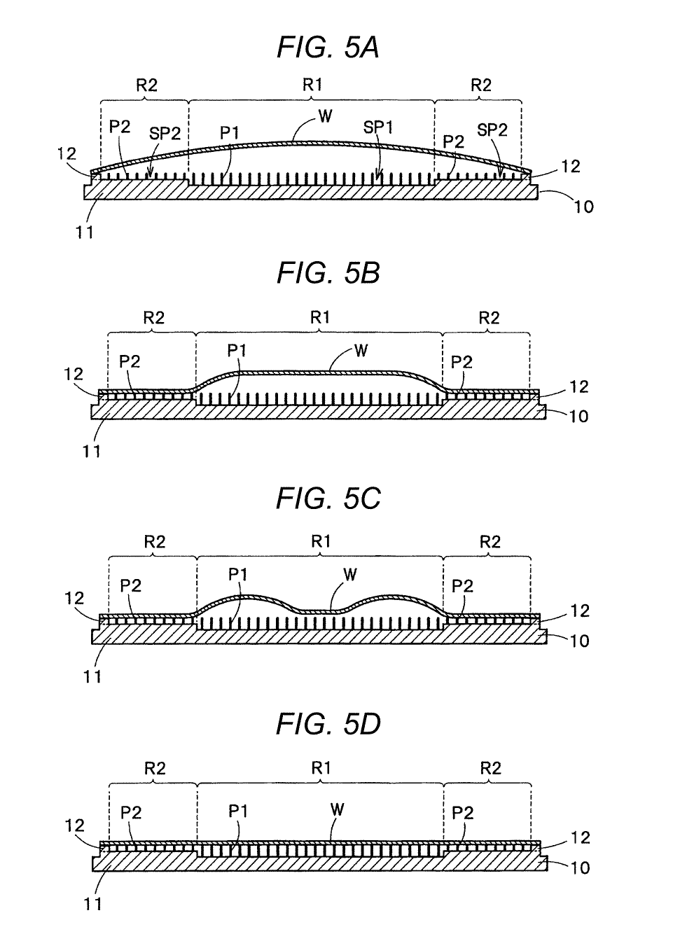

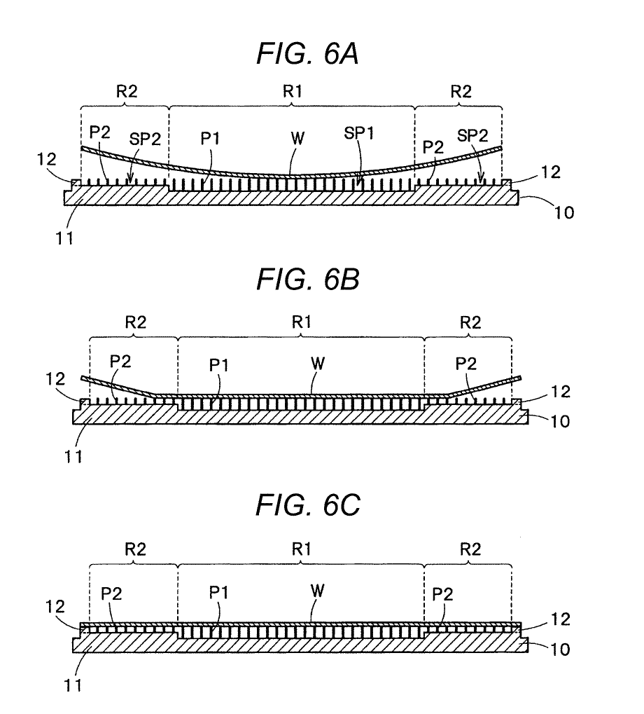

FIG. 4 is a flowchart illustrating an example of a substrate holding method according to some embodiments. FIGS. 5A to 6C are sectional views illustrating an example of a substrate holding method according to some embodiments. The control sequence for holding the substrate W in a planar shape by correcting the distortion of the substrate W will be described with reference to FIGS. 4 and 5A to 6C.

### Convex (or Projection-Shaped) Distortion

First, in some embodiments, the substrate W is placed on the stage 10 (S10). Next, in some embodiments, the controller 50 obtains the shape information of the substrate W that is stored in the database 40 (S20). In some embodiments, the controller 50 determines whether the shape information of the substrate W indicates a convex (or projection-shaped) distortion or a concave (or recess-shaped) distortion (S30). In some embodiments, in a case where the shape information indicates a convex (or projection-shaped) distortion illustrated in FIG. 3A, when the substrate W is placed on the stage 10, as illustrated in FIG. 5A, the end portions of the substrate W in the second regions R2 are closer to the stage 10 than the center portion of the substrate W in the first region R1. In some embodiments, although the end portions of the substrate W are brought into contact with the stage 10, the center portion of the substrate W is separated from the stage 10. At this time, in some embodiments, the controller 50 executes the control sequence corresponding to the convex (or projection-shaped) distortion as follows.

In some embodiments, in an initial state, the valves V1 to V4 are closed.

In some embodiments, the controller 50 controls the valves V1 to V4 so as to depressurize the first and second spaces SP1 and SP2 in the order from the region where the distance between the substrate W and the convex portions P1 and P2 is close to the region where the distance between the substrate W and the convex portions P1 and P2 is far. For example, the controller 50 opens the valves V4, V3, V2, and V1 in this order (S40). That is, the controller 50 depressurizes the second spaces SP2 by the second depressurization unit VS2, and then depressurizes the first space SP1 by the first depressurization unit VS1. Accordingly, as illustrated in FIG. 5B, the substrate W is gradually drawn to the stage 10 from the end portions of the substrate W toward the center portion of the substrate W. In this case, when the valves V1 to V4 are all opened, as illustrated in FIG. 5C, the distortion on the substrate W may remain in some cases.

Next, the controller 50 closes the valves V2 to V4 while maintaining the state where the valve V1 at the center portion of the substrate W is opened (S50). That is, while maintaining the depressurization operation of the first space SP1 by the first depressurization unit VS1 (for example, here, the exhaust pipes PL1 and the valve V1), the controller 50 stops the depressurization operation of the first space SP1 by the exhaust pipes PL2 and the valve V2 and the depressurization operation of the second space SP2 by the second depressurization unit VS2. Accordingly, while applying suction to the center portion of the substrate W to the stage 10, the end portions of the substrate W can be opened, and thus it is possible to remove the distortion remained on the substrate W. At this time, although the valve V2 is also closed, when the degree of the convex (or projection-shaped) distortion of the substrate W is high, the valve V2 may be opened together with the valve V1. Accordingly, it is possible to reliably apply suction to the center portion of the substrate W to the stage 10.

Next, the controller 50 opens the valves V2 to V4 in the order from the valve close to the center portion of the substrate W. In some embodiments, the valves V2, V3 and V4 are opened in this order (S60). That is, the controller 50 executes again the depressurization operation of the first space SP1 by the exhaust pipes PL2 and the valve V2 and the depressurization operation of the second space SP2 by the second depressurization unit VS2. Accordingly, as illustrated in FIG. 5D, the substrate W is gradually drawn to the stage 10 from the center portion of the substrate W toward the end portions of the substrate W without a distortion. In step S40, when the valve V2 is opened together with the valve V1, the controller 50 may open the valves V3 and V4 in this order.

Next, the controller 50 closes the valves V1 to V3 while maintaining the state where the valve V4 corresponding to the end portions of the substrate W is opened (S90). That is, while maintaining the depressurization operation of the second space SP2 by the second depressurization unit VS2 (for example, here, the exhaust pipes PL4 and the valve V4), the controller 50 stops the depressurization operation of the first space SP1 by the first depressurization unit VS1. Since the valve V4 is opened, the substrate W can be drawn to the stage 10 in the second region R2, and thus the end portions of the substrate W can be brought into close contact with the partition portions 12. Therefore, even when the valves V1 to V3 are closed, while maintaining the state where the end portions of the substrate W are brought into close contact with the partition portions 12, the depressurization state of the first space SP1 and the second space SP2 can be maintained. On the other hand, the valves V1 to V3 are closed, and thus the force that is applied to the substrate W is suppressed. Therefore, it is possible to reduce a distortion due to the suction to the stage 10. At this time, although the valve V3 is also closed, when the degree of the convex (or projection-shaped) distortion of the substrate W is high, the valve V3 may be opened together with the valve V4. Accordingly, the end portions of the substrate W are reliably brought into close contact with the partition portions 12, and thus the depressurization state of the first space SP1 and the second space SP2 can be more reliably maintained.

### Concave (or Recess-Shaped) Distortion

In the step S30, in a case where the shape information indicates a concave (or recess-shaped) distortion illustrated in FIG. 3B, when the substrate W is placed on the stage 10, as illustrated in FIG. 6A, the center portion of the substrate W in the first regions R1 is closer to the stage 10 than the end portions of the substrate W in the second region R2. Therefore, although the center portion of the substrate W is brought into contact with the stage 10, the end portions of the substrate W are separated from the stage 10. At this time, the controller 50 executes the control sequence corresponding to the concave (or recess-shaped) distortion as follows.

The controller 50 controls the valves V1 to V4 so as to depressurize the first and second spaces SP1 and SP2 in the order from the region where the distance between the substrate W and the convex portions P1 and P2 is close to the region where the distance between the substrate W and the convex portions P1 and P2 is far. For example, the controller 50 opens the valves V1, V2, V3, and V4 in this order (S80). That is, the controller 50 depressurizes the first space SP1 by the first depressurization unit VS1, and then depressurizes the second spaces SP2 by the second depressurization unit VS2. Accordingly, as illustrated in FIG. 6B, the substrate W is gradually drawn to the stage 10 from the center portion of the substrate W toward the end portions of the substrate W. In this case, when the valves V1 to V4 are all opened, as illustrated in FIG. 6C, the substrate W is gradually drawn to the stage 10 from the center portion of the substrate W toward the end portions of the substrate W without a distortion.

Next, the controller 50 closes the valves V1 to V3 while maintaining the state where the valve V4 corresponding to the end portions of the substrate W is opened (S90). That is, while maintaining the depressurization operation of the second space SP2 by the second depressurization unit VS2 (for example, here, the exhaust pipes PL4 and the valve V4), the controller 50 stops the depressurization operation of the first space SP1 by the first depressurization unit VS1. The operation in the step S90 may be the same as the operation in the case where the substrate W has the convex (or projection-shaped) distortion. Accordingly, it is possible to maintain the depressurization state of the first and second spaces SP1 and SP2 while maintaining the state where the end portions of the substrate W are brought into close contact with the partition portions 12.

As described above, the substrate holding apparatus 1 according to some embodiments individually (or independently) controls the valves V1 to V4, and changes the order of the depressurization operation by the valves V1 to V4 based on the shape of the substrate W. According to some embodiments, the substrate holding apparatus 1 controls the valves V1 to V4 so as to depressurize the first and second spaces SP1 and SP2 in the order from the region where the distance between the substrate W and the stage 10 is close to the region where the distance between the substrate W and the stage 10 is far. That is, in some embodiments, the controller 50 is configured to control the valves V1 to V4 so as to depressurize the first space SP1 and the second space SP2 in the order from a region having a first distance between the substrate W and the stage 10 to a region having a second distance between the substrate W and the stage 10 such that the second distance is greater than the first distance. Accordingly, it is possible to apply suction to the substrate W on the stage 10 regardless of the shape of the distortion of the substrate W. In some embodiments, even when suction is applied to the substrate W on the stage 10, in a case where the distortion remains on the substrate W, the end portions of the substrate W are temporarily opened while maintaining the state where the center portion of the substrate W is drawn to the stage 10, and thus the distortion remained in the vicinity of the center portion of the substrate W is removed. Thereafter, in some embodiments, the substrate holding apparatus 1 controls again the valves V1 to V4 so as to depressurize the first and second spaces SP1 and SP2 in the order from the center portion of the substrate W where the distance between the substrate W and the placing portion is close to the end portions of the substrate W where the distance between the substrate W and the placing portion is far. That is, in some embodiments, the controller 50 is configured to control the valves V1 to V4 so as to depressurize the first space SP1 and the second space SP2 in the order from the center portion of the substrate W having a first distance between the substrate W and the placing portion to the end portions of the substrate W having a second distance between the substrate W and the placing portion such that the second distance is greater than the first distance. Accordingly, the substrate W can be gradually drawn to the stage 10 from the center portion thereof toward the end portions thereof without a distortion. Therefore, the substrate holding apparatus 1 according to some embodiments can apply suction to the substrate W on the stage 10 regardless of the shape of the distortion of the substrate W, by correcting the shape of the substrate W into a planar shape.

Further, according to some embodiments, in the D1 direction, the first surface F1 in the second region R2 is higher than the first surface F1 in the first region R1, and is close to the substrate W to which suction is applied on the stage 10. Therefore, the stage 10 can apply suction to the end portions of the substrate W more strongly, and thus the end portions of the substrate W can be brought well into close contact with the partition portions 12. As a result, after applying suction to the substrate W, the substrate holding apparatus 1 closes the valves V1 to V3 among the valves V1 to V4 and opens only the valve V4 closest to the outer edge of the substrate W, and thus the substrate W can be drawn to the stage 10.

In some embodiments, the number of the depressurization units and the number of the exhaust systems may be two or more, but are not particularly limited. In some embodiments, the number of the regions on the first face F1 of the support portion 11 may be two or more, but is not particularly limited. For example, the first surface F1 of the stage 10 may be further concentrically divided into third to n-th regions (n is an integer of three or more) between the first region R1 and the second region R2. In some embodiments, the first surface F1 may be concentrically divided into the first to n-th regions R1 to Rn (not illustrated). In some embodiments, the heights of the first to n-th regions R1 to Rn in the D1 direction may be different from each other. In some embodiments, the substrate holding apparatus 1 may further include third to n-th depressurization units that respectively depressurize the spaces between the substrate W and the third to n-th regions R3 to Rn. In some embodiments, the controller 50 can individually control the first to n-th depressurization units. Accordingly, the substrate holding apparatus 1 can apply suction to the substrate W to the stage 10 by correcting the shape of the substrate W into a planar shape through more stages. For example, when n=4, the first to fourth depressurization units may be configured so as to correspond to the valves V1 to V4. In some embodiments, the depressurization units may be respectively configured for the plurality of valves. In some embodiments, the depressurization units may be configured regardless of the number of the valves. Therefore, as in some embodiments, the first system and the second system (the exhaust pipes PL1, the valve V1, the exhaust pipes PL2, and the valve V2) may be set as the first depressurization unit VS1, and the third system and the fourth system (the exhaust pipes PL3, the valve V3, the exhaust pipes PL4, and the valve V4) may be set as the second depressurization unit VS2.

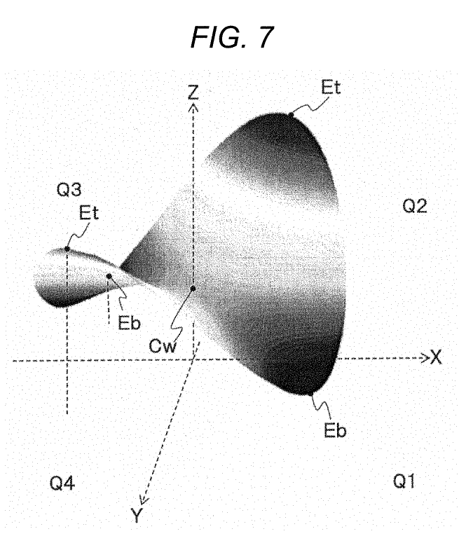

As illustrated in FIG. 7, in some embodiments, a substrate W may have a saddle-shaped distortion in some cases, in addition to the convex (or projection-shaped) distortion or the concave (or recess-shaped) distortion. For example, FIG. 7 is a graph illustrating the distortion measurement result of a substrate W with a saddle-shaped distortion. For ease of understanding, the coordinate axes in FIG. 7 are set to be different from the coordinate axes in FIGS. 3A and 3B, for the sake of convenience.

For example, in the substrate W with a saddle-shaped distortion, in the first quadrant Q1 and the third quadrant Q3, the center portion Cw of the substrate W is further projected in a direction (+Z direction) farther away from the stage 10 than the lower end portions Eb of the substrate W. That is, in some embodiments, in the first quadrant Q1 and the third quadrant Q3, the lower end portions Eb of the substrate W are fallen toward the −Z direction. In some embodiments, in the second quadrant Q2 and the fourth quadrant Q4, the center portion Cw of the substrate W is further projected in a direction (−Z direction) close to the stage 10 than the upper end portions Et of the substrate W. That is, in some embodiments, in the second quadrant Q2 and the fourth quadrant Q4, the upper end portions Et of the substrate W are raised toward the +Z direction. Here, such a distortion is called as a saddle-shaped distortion. The substrate holding apparatus 2 according to some embodiments applies suction to the substrate W with a saddle-shaped distortion by correcting the shape of the substrate W into a planar shape.

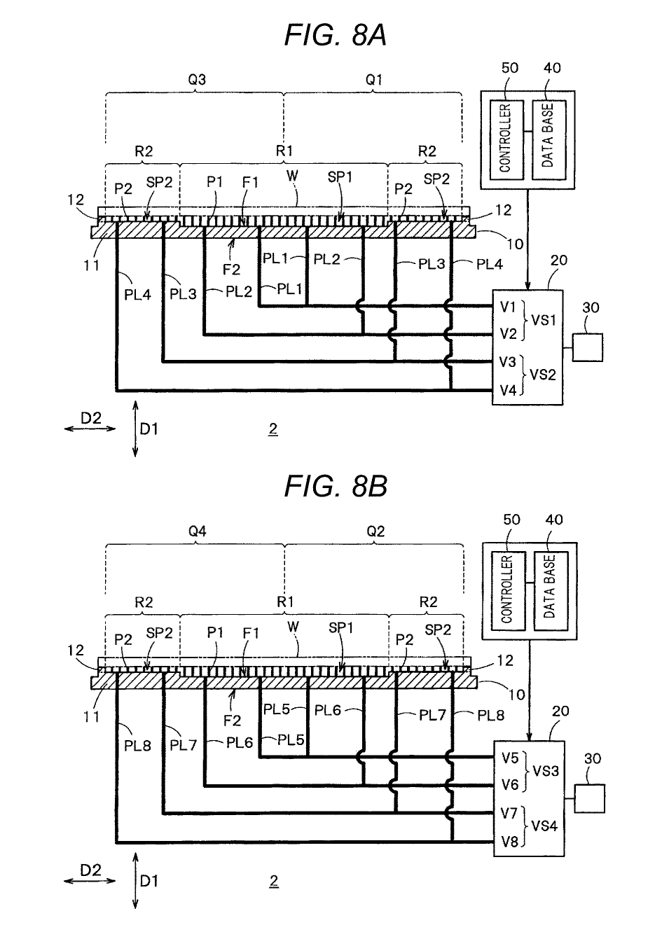

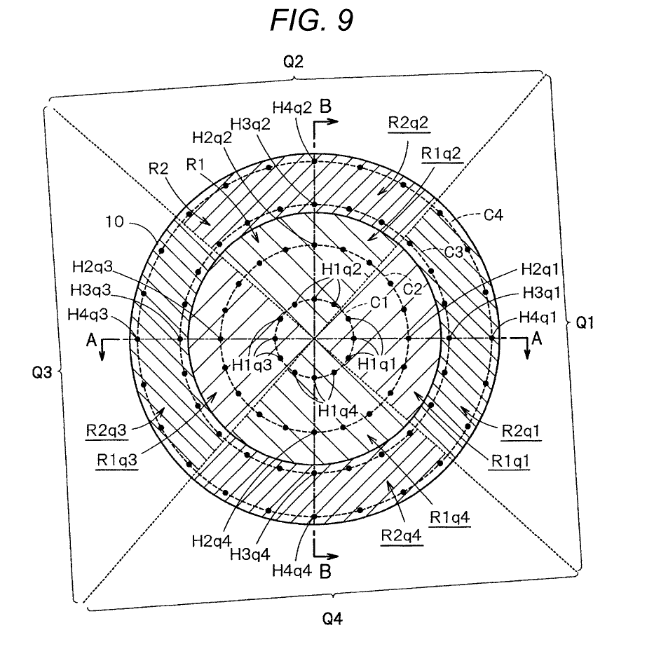

FIGS. 8A and 8B are diagrams illustrating a configuration example of a substrate holding apparatus 2 according to some embodiments. FIG. 9 is a plan view illustrating a configuration example of a stage 10 according to some embodiments. The section taken along the line A-A in FIG. 9 corresponds to the stage 10 in FIG. 8A. The section taken along the line B-B in FIG. 9 corresponds to the stage 10 in FIG. 8B.

The shape of the stage 10 may be basically the same as the shape of the stage 10 according to the embodiments illustrated in FIGS. 1-6C. Therefore, in some embodiments, the stage 10 includes the first convex portions P1 on the first region R1 of the first surface F1 and the second convex portions P2 on the second regions R2 of the first surface F1. In some embodiments, the exhaust holes H1 to H4 are respectively arranged on virtual broken-line circles C1 to C4 on the first surface F1 of the stage 10. The number of each of the convex portions P1 and P2 and the number of each of the exhaust holes H1 to H4 are not particularly limited.

On the other hand, in some embodiments, in order to correct the shape of the substrate W with a saddle-shaped distortion into a planar shape, as illustrated in FIG. 9, the first surface F1 of the stage 10 is divided into four quadrants of the first quadrant Q1 to the fourth quadrant Q4. In some embodiments, this plane coordinate is a plane coordinate whose origin is the center of the first surface F1.

In some embodiments, exhaust holes H1q1 and H1q3 in the first quadrant Q1 and the third quadrant Q3 are connected to the exhaust pipes PL1 and the valve V1 (a first system) illustrated in FIG. 8A. In some embodiments, exhaust holes H2q1 and H2q3 in the first quadrant Q1 and the third quadrant Q3 are connected to the exhaust pipes PL2 and the valve V2 (a second system) illustrated in FIG. 8A. In some embodiments, exhaust holes H3q1 and H3q3 in the first quadrant Q1 and the third quadrant Q3 are connected to the exhaust pipes PL3 and the valve V3 (a third system) illustrated in FIG. 8A. In some embodiments, exhaust holes H4q1 and H4q3 in the first quadrant Q1 and the third quadrant Q3 are connected to the exhaust pipes PL4 and the valve V4 (a fourth system) illustrated in FIG. 8A.

In some embodiments, exhaust holes H1q2 and H1q4 in the second quadrant Q2 and the fourth quadrant Q4 are commonly connected to Exhaust pipes PL5 and a valve V5 (a fifth system) illustrated in FIG. 8B. In some embodiments, exhaust holes H2q2 and H2q4 in the second quadrant Q2 and the fourth quadrant Q4 are commonly connected to the exhaust pipes PL6 and a valve V6 (a sixth system) illustrated in FIG. 8B. In some embodiments, exhaust holes H3q2 and H3q4 in the second quadrant Q2 and the fourth quadrant Q4 are commonly connected to exhaust pipes PL7 and a valve V7 (a seventh system) illustrated in FIG. 8B. In some embodiments, exhaust holes H4q2 and H4q4 in the second quadrant Q2 and the fourth quadrant Q4 are commonly connected to exhaust pipes PL8 and a valve V8 (an eighth system) illustrated in FIG. 8B.

In some embodiments, the exhaust pipes PL1 to PL4 and the valves V1 to V4 illustrated in FIG. 8A are connected to the first quadrant Q1 of the stage 10 and the third quadrant Q3 of the stage 10. In some embodiments, the exhaust pipes PL1 to PL4 and the valves V1 to V4 are not connected to the second quadrant Q2 and the fourth quadrant Q4. In some embodiments, the configurations of the exhaust pipes PL1 to PL4 and the valves V1 to V4 may be basically the same as those of the embodiments illustrated in FIGS. 1-6C.

In some embodiments, the exhaust pipes PL5 to PL8 and the valves V5 to V8 illustrated in FIG. 8B are connected to the second quadrant Q2 of the stage 10 and the fourth quadrant Q4 of the stage 10. The exhaust pipes PL5 to PL8 and the valves V5 to V8 according to some embodiments are different from the exhaust pipes PL1 to PL4 and the valves V1 to V4 according to the embodiments illustrated in FIGS. 1-6C in that the exhaust pipes PL5 to PL8 and the valves V5 to V8 are not connected to the first quadrant Q1 and the third quadrant Q3. In some embodiments, the configurations of the exhaust pipes PL5 to PL8 and the valves V5 to V8 may be basically the same as those of the exhaust pipes PL1 to PL4 and the valves V1 to V4, respectively.

In some embodiments, the vacuum pump 30, the database 40, and the controller 50 may be separately provided for each of the valves V1 to V4 and the valves V5 to V8. In some embodiments, in order to reduce the size and the cost of the substrate holding apparatus 2, the vacuum pump 30, the database 40, and the controller 50 are commonly used.

In some embodiments, the exhaust system including the exhaust pipes PL1, the valve V1, and the vacuum pump 30 is set as the first system, the exhaust system including the exhaust pipes PL2, the valve V2, and the vacuum pump 30 is set as the second system, the exhaust system including the exhaust pipes PL3, the valve V3, and the vacuum pump 30 is set as the third system, and the exhaust system including the exhaust pipes PL4, the valve V4, and the vacuum pump 30 is set as the fourth system. In some embodiments, the exhaust system including the exhaust pipes PL5, the valve V5, and the vacuum pump 30 is set as the fifth system, the exhaust system including the exhaust pipes PL6, the valve V6, and the vacuum pump 30 is set as the sixth system, the exhaust system including the exhaust pipes PL7, the valve V7, and the vacuum pump 30 is set as the seventh system, and the exhaust system including the exhaust pipes PL8, the valve V8, and the vacuum pump 30 is set as the eighth system.

In some embodiments, the first depressurization unit VS1 is either or both of the first system (the exhaust pipes PL1 and the valve V1) and the second system (the exhaust pipes PL2 and the valve V2). In some embodiments, in the first quadrant Q1 and the third quadrant Q3, the first depressurization unit VS1 depressurizes the space between the substrate W and the first regions (R1q1 and R1q3). In some embodiments, the second depressurization unit VS2 is either or both of the third system (the exhaust pipes PL3 and the valve V3) and the fourth system (the exhaust pipes PL4 and the valve V4). In some embodiments, in the first quadrant Q1 and the third quadrant Q3, the second depressurization unit VS2 depressurizes the space between the substrate W and the second regions (R2q1 and R2q3). In some embodiments, the third depressurization unit VS3 is either or both of the fifth system (the exhaust pipes PL5 and the valve V5) and the sixth system (the exhaust pipes PL6 and the valve V6). In some embodiments, in the second quadrant Q2 and the fourth quadrant Q4, the third depressurization unit VS3 depressurizes the space between the substrate W and the first regions (R1q2 and R1q4). In some embodiments, the fourth depressurization unit VS4 is either or both of the seventh system (the exhaust pipes PL7 and the valve V7) and the eighth system (the exhaust pipes PL8 and the valve V8). In some embodiments, in the second quadrant Q2 and the fourth quadrant Q4, the fourth depressurization unit VS4 depressurizes the space between the substrate W and the second regions (R2q2 and R2q4).

In some embodiments, the controller 50 can individually (or independently) control each of the first system to the eighth system based on the shape information of the substrate W from the database 40. Accordingly, the controller 50 can individually control each of the first depressurization unit VS1 to the fourth depressurization unit VS4.

Next, a substrate holding method using the substrate holding apparatus 2 will be described.

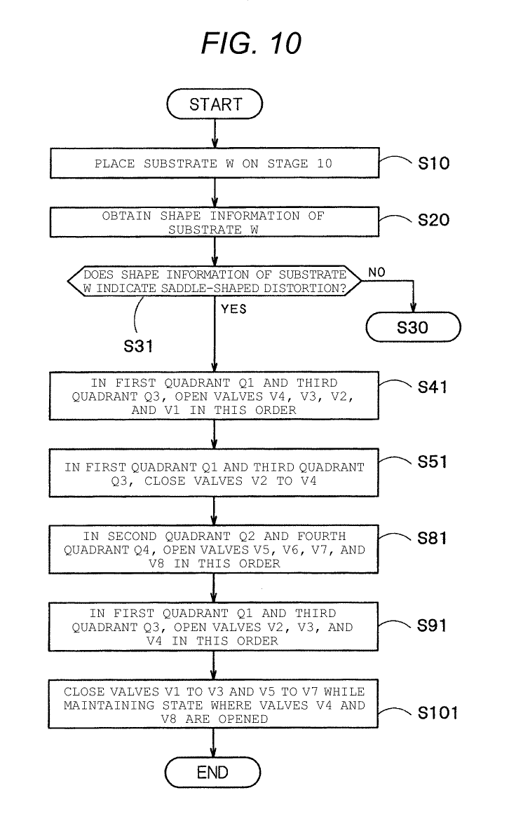

FIG. 10 is a flowchart illustrating an example of a substrate holding method according to some embodiments. First, in some embodiments, the substrate W is arranged on the stage 10 (S10). Next, in some embodiments, the controller 50 obtains the shape information of the substrate W that is stored in the database 40 (S20). In some embodiments, the controller 50 determines the shape of the substrate W (S31).

In some embodiments, in a case where the shape information indicates a saddle-shaped distortion illustrated in FIG. 7 (YES in S31), when the substrate W is placed on the stage 10, in the first quadrant Q1 and the third quadrant Q3, the lower end portions Eb of the substrate W illustrated in FIG. 7 are closer to the stage 10 than the center portion Cw of the substrate W. Therefore, although the lower end portions Eb of the substrate W are brought into contact with the stage 10, the center portion Cw of the substrate W is separated from the stage 10. At this time, the controller 50 executes the control sequence corresponding to the convex (or projection-shaped) distortion according to the embodiments illustrated in FIGS. 1-6C. That is, as described above with reference to FIGS. 5A to 5D, in the first quadrant Q1 and the third quadrant Q3, the controller 50 operates the first depressurization unit VS1 and the second depressurization unit VS2 illustrated in FIG. 8A.

In some embodiments, in the first quadrant Q1 and the third quadrant Q3, the controller 50 depressurizes the space between the substrate W and the second regions (R2q1 and R2q3) by the second depressurization unit VS2, and then, depressurizes the space between the substrate W and the first regions (R1q1 and R1q3) by the first depressurization unit VS1. For example, the controller 50 opens the valves V4, V3, V2, and V1 in this order (S41). Accordingly, in some embodiments, the substrate W is gradually drawn to the stage 10 from the lower end portions Eb of the substrate W toward the center portion Cw of the substrate W.

Next, in some embodiments, in the first quadrant Q1 and the third quadrant Q3, the controller 50 stops the depressurization operation by the second depressurization unit VS2 while maintaining the depressurization operation by at least a portion of the first depressurization unit VS1. For example, the controller 50 closes the valves V2 to V4 while maintaining the state where the valve V1 is opened (S51). Accordingly, in some embodiments, while applying suction to the center portion Cw of the substrate W to the stage 10, the lower end portions Eb of the substrate W can be opened, and thus it is possible to remove the distortion remained on the substrate W.

At this time, in some embodiments, in the second quadrant Q2 and the fourth quadrant Q4, the upper end portions Et of the substrate W illustrated in FIG. 7 are further raised in a direction away from the stage 10 than the center portion Cw of the substrate W. Therefore, in some embodiments, although the center portion Cw of the substrate W is drawn to the stage 10, the upper end portions Et of the substrate W are separated from the stage 10. Thus, in some embodiments, the controller 50 executes the control sequence corresponding to the concave (or recess-shaped) distortion according to the embodiments illustrated in FIGS. 1-6C. That is, in some embodiments, in the second quadrant Q2 and the fourth quadrant Q4, the controller 50 operates the third depressurization unit VS3 and the fourth depressurization unit VS4 illustrated in FIG. 8B. Accordingly, in some embodiments, as described above with reference to FIGS. 6A to 6C, the upper end portions Et of the substrate W are drawn to the stage 10.

In some embodiments, in the second quadrant Q2 and the fourth quadrant Q4, the controller 50 depressurizes the space between the substrate W and the first regions (R1q2 and R1q4) by the third depressurization unit VS3, and then, depressurizes the space between the substrate W and the second regions (R2q2 and R2q4) by the fourth depressurization unit VS4. For example, the controller 50 opens the valves V5, V6, V7, and V8 in this order (S81). Accordingly, in some embodiments, the substrate W is gradually drawn to the stage 10 from the center portion Cw of the substrate W toward the upper end portions Et of the substrate W.

Next, in some embodiments, in the first quadrant Q1 and the third quadrant Q3, the controller 50 depressurizes again the space between the substrate W and the second regions (R2q1 and R2q3) by the second depressurization unit VS2. For example, the controller 50 opens the valves V2, V3, and V4 in this order (S91). At this step, in some embodiments, all of the valves V1 to V8 are opened, and all of the first depressurization unit VS1 to the fourth depressurization unit VS4 execute the depressurization operation. In some embodiments, the whole of the substrate W is drawn to the stage 10 by correcting the shape of the substrate W into a planar shape.

Thereafter, in some embodiments, in the first quadrant to the fourth quadrant, the controller 50 stops the depressurization operation by the first depressurization unit VS1 and the third depressurization unit VS3 while maintaining the depressurization operation by the second depressurization unit VS2 and the fourth depressurization unit VS4. For example, the controller 50 closes the valves V1 to V3 and V5 to V7 while maintaining the state where the valves V4 and V8 connected to the end portions of the stage 10 are opened (S101). Accordingly, in some embodiments, the end portions Eb and Et of the substrate W are brought into close contact with the partition portion 12, and thus it is possible to reduce the distortion due to the suction to the stage 10 while maintaining the depressurization state between the substrate W and the stage 10.

In step S31, in some embodiments, in the case of the substrate W with no saddle-shaped distortion (NO in S31), the process may proceed to step S30 in FIG. 4, or the substrate holding operation may be ended.

The substrate holding apparatus 2 according to some embodiments can apply suction to the substrate W on the stage 10 in a planar shape even when the substrate W has a saddle-shaped distortion. Further, in some embodiments, the same effects as those of the embodiments illustrated in FIGS. 1-6C can be obtained. In some embodiments, the substrate holding apparatus 2 may operate the first depressurization unit VS1 and the third depressurization unit VS3 in the same manner, and operate the second depressurization unit VS2 and the fourth depressurization unit VS4 in the same manner, regardless of the first quadrant Q1 to the fourth quadrant Q4. In some embodiments, the substrate holding apparatus 2 can also execute the control sequence according to the embodiments illustrated in FIGS. 1-6C.

In some embodiments, the first surface F1 of the substrate W is radially divided into four from the center of the first surface F1. However, the number of divisions of the first surface F1 is not particularly limited. In some embodiments, in a case where the first surface F1 is radially divided into m (m is an integer of two or more), the substrate holding apparatus 2 may include m exhaust pipes PL1 to PLm and m valves V1 to Vm. In some embodiments, the controller 50 may individually control the m valves V1 to Vm. Accordingly, in some embodiments, the substrate holding apparatus 2 can apply suction to the substrate W to the stage 10 by correcting the shape of the substrate W into a planar shape through more stages.

While certain embodiments have been described, these embodiments have been presented by way of example only, and are not intended to limit the scope of the present disclosure. Indeed, the embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

What is claimed is:

1. A substrate holding apparatus comprising:
a placing portion that includes a plurality of convex portions configured to support a substrate, and includes a first region which faces a center portion of the substrate and second regions which face outer peripheral portions of the substrate;
a first depressurization unit configured to depressurize a space between the substrate and the first region;
a second depressurization unit configured to depressurize a space between the substrate and the second regions;
a storage unit configured to store shape information of the substrate; and
a control unit configured to individually control each of the first depressurization unit and the second depressurization unit based on the shape information.

2. The apparatus according to claim 1,
wherein the second regions are positioned at a position higher than a position of the first region in a direction which faces the substrate.

3. The apparatus according to claim 1,
wherein the control unit is configured to change the order of the depressurization operations of the first depressurization unit and the second depressurization unit according to the shape information.

4. The apparatus according to claim 2,
wherein the control unit is configured to change the order of the depressurization operations of the first depressurization unit and the second depressurization unit according to the shape information.

5. The apparatus according to claim 1,
wherein the control unit is configured to control the first depressurization unit and the second depressurization unit so as to depressurize the first region and the second regions in the order from a region having a first distance between the substrate and the placing portion to a region having a second distance between the substrate and the placing portion such that the second distance is greater than the first distance.

6. The apparatus according to claim 2,
wherein the control unit is configured to control the first depressurization unit and the second depressurization unit so as to depressurize the first region and the second regions in the order from a region having a first distance between the substrate and the placing portion to a region having a second distance between the substrate and the placing portion such that the second distance is greater than the first distance.

7. The apparatus according to claim 3,
wherein the control unit is configured to control the first depressurization unit and the second depressurization unit so as to depressurize the first region and the second regions in the order from a region having a first distance between the substrate and the placing portion to a region having a second distance between the substrate and the placing portion such that the second distance is greater than the first distance.

8. The apparatus according to claim 1,
wherein the first depressurization unit is configured to depressurize a space between the substrate and the first region in a first quadrant and a third quadrant of a plane coordinate system in which a center of a surface of the placing portion is set as an origin,
wherein the second depressurization unit is configured to depressurize a space between the substrate and the second regions in the first quadrant and the third quadrant of the plane coordinate system,
the apparatus further comprising:
a third depressurization unit configured to depressurize a space between the substrate and the first region in a second quadrant and a fourth quadrant of the plane coordinate system,
a fourth depressurization unit configured to depressurize a space between the substrate and the second regions in the second quadrant and the fourth quadrant of the plane coordinate system,
wherein the control unit is configured to individually control each of the first depressurization unit to the fourth depressurization unit based on the shape information.

9. The apparatus according to claim 2,
wherein the first depressurization unit is configured to depressurize a space between the substrate and the first region in a first quadrant and a third quadrant of a plane coordinate system in which a center of a surface of the placing portion is set as an origin,
wherein the second depressurization unit is configured to depressurize a space between the substrate and the second regions in the first quadrant and the third quadrant of the plane coordinate system,
the apparatus further comprising:
a third depressurization unit configured to depressurize a space between the substrate and the first region in a second quadrant and a fourth quadrant of the plane coordinate system,
a fourth depressurization unit configured to depressurize a space between the substrate and the second regions in the second quadrant and the fourth quadrant of the plane coordinate system,
wherein the control unit is configured to individually control each of the first depressurization unit to the fourth depressurization unit based on the shape information.

10. The apparatus according to claim 3,
wherein the first depressurization unit is configured to depressurize a space between the substrate and the first region in a first quadrant and a third quadrant of a plane coordinate system in which a center of a surface of the placing portion is set as an origin,
wherein the second depressurization unit is configured to depressurize a space between the substrate and the second regions in the first quadrant and the third quadrant of the plane coordinate system,
the apparatus further comprising:
a third depressurization unit configured to depressurize a space between the substrate and the first region in a second quadrant and a fourth quadrant of the plane coordinate system,
a fourth depressurization unit configured to depressurize a space between the substrate and the second regions in the second quadrant and the fourth quadrant of the plane coordinate system,
wherein the control unit is configured to individually control each of the first depressurization unit to the fourth depressurization unit based on the shape information.

11. The apparatus according to claim 5,
wherein the first depressurization unit is configured to depressurize a space between the substrate and the first region in a first quadrant and a third quadrant of a plane coordinate system in which a center of a surface of the placing portion is set as an origin,
wherein the second depressurization unit is configured to depressurize a space between the substrate and the second regions in the first quadrant and the third quadrant of the plane coordinate system,
the apparatus further comprising:
a third depressurization unit configured to depressurize a space between the substrate and the first region in a second quadrant and a fourth quadrant of the plane coordinate system,
a fourth depressurization unit configured to depressurize a space between the substrate and the second regions in the second quadrant and the fourth quadrant of the plane coordinate system,
wherein the control unit is configured to individually control each of the first depressurization unit to the fourth depressurization unit based on the shape information.

12. The apparatus according to claim 1,
wherein the placing portion further includes third to n-th regions (n is an integer of three or more) that are concentrically divided between the first region and the second regions,
the apparatus further comprising:
third to n-th depressurization units configured to respectively depressurize the space between the substrate and the third to n-th regions,
wherein the control unit is further configured to individually control each of the first to the n-th depressurization units based on the shape information.

13. The apparatus according to claim 2,
wherein the placing portion further includes third to n-th regions (n is an integer of three or more) that are concentrically divided between the first region and the second regions,
the apparatus further comprising:
third to n-th depressurization units configured to respectively depressurize the space between the substrate and the third to n-th regions,
wherein the control unit is further configured to individually control each of the first to the n-th depressurization units based on the shape information.

14. The apparatus according to claim 3,
wherein the placing portion further includes third to n-th regions (n is an integer of three or more) that are concentrically divided between the first region and the second regions,
the apparatus further comprising:
third to n-th depressurization units configured to respectively depressurize the space between the substrate and the third to n-th regions,
wherein the control unit is further configured to individually control each of the first to the n-th depressurization units based on the shape information.

15. The apparatus according to claim 5,
wherein the placing portion further includes third to n-th regions (n is an integer of three or more) that are concentrically divided between the first region and the second regions,
the apparatus further comprising:
third to n-th depressurization units configured to respectively depressurize the space between the substrate and the third to n-th regions,
wherein the control unit is further configured to individually control each of the first to the n-th depressurization units based on the shape information.

16. The apparatus according to claim 8,
wherein the placing portion further includes third to n-th regions (n is an integer of three or more) that are concentrically divided between the first region and the second regions,
the apparatus further comprising:
third to n-th depressurization units configured to respectively depressurize the space between the substrate and the third to n-th regions,
wherein the control unit is further configured to individually control each of the first to the n-th depressurization units based on the shape information.
